(19) United States
(12) Patent Application Publication
(10) Pub. No.: US 2012/0068235 A1
(43) Pub. Date: Mar. 22, 2012

(54) INTEGRATED CIRCUIT

(75) Inventors: Yoshiyuki Kondo, Yokohama-Shi (JP); Shigeru Kawanaka, Yokohama-Shi (JP)

(73) Assignee: KABUSHIKI KAISHA TOSHIBA, Tokyo (JP)

(21) Appl. No.: 13/230,066

(22) Filed: Sep. 12, 2011

(30) Foreign Application Priority Data
Sep. 16, 2010 (JP) 2010-208272

(51) Int. Cl. H01L 27/088

(52) U.S. Cl. 257/295; 257/E27.06

(57) ABSTRACT

In accordance with an embodiment, an integrated circuit includes a first spin transistor and a second spin transistor. The first spin transistor has a first channel length. The first spin transistor includes a first node and a second node apart from the first node The second spin transistor is connected to the first transistor in series and has a second channel length different from the first channel length. The second spin transistor includes a third node and a fourth node apart from the third node The second node and the fourth node are electrically connected to each other.

### CROSS REFERENCE TO RELATED APPLICATIONS

This application is based upon and claims the benefit of priority from the prior Japanese Patent Application No. 2010-208272, filed on Sep. 16, 2010, the entire contents of which are incorporated herein by reference.

### FIELD

Embodiments described herein relate generally to an integrated circuit.

### BACKGROUND

Recently, there has been known a spin FET. The spin FET uses, as a channel, a two dimensional electron gas (2 DEG) induced at the interface of a modulation-doped structure comprising, for example, an InAlAs/InGaAs heterojunction, and uses a ferromagnetic body for a source and a drain.

### BRIEF DESCRIPTION OF THE DRAWINGS

FIG. 1A is a schematic diagram of a spin transistor according to a first embodiment;

FIG. 1B is a schematic diagram illustrating the basic operation of the spin transistor;

FIG. 1C is a schematic diagram concerning a relative angle between the direction of majority spins of a magnetic body of a drain region and a spin deflection vector of an electron in a channel;

FIG. 2 is a current-voltage (I-V) curve of the spin transistor according to the first embodiment;

FIG. 3 is a schematic diagram of an inverter circuit that uses two spin transistors according to the first embodiment;

FIG. 4A is a schematic diagram concerning the operation of a first spin transistor when V_{low} is input as Vᵢₙ in the first embodiment;

FIG. 4B is a schematic diagram concerning the operation of a second spin transistor when V_{low} is input as Vᵢₙ in the first embodiment;

FIG. 4C is a schematic diagram concerning the operation of the first spin transistor when V_{high} is input as Vᵢₙ in the first embodiment;

FIG. 4D is a schematic diagram concerning the operation of the second spin transistor when V_{high} is input as Vᵢₙ in the first embodiment;

FIG. 5 is a schematic diagram of an integrated circuit according to a second embodiment;

FIG. 6 is a schematic diagram of an integrated circuit according to a third embodiment;

FIG. 7A is a schematic diagram concerning the operation of a first spin transistor when V_{low} is input as Vᵢₙ in the third embodiment;

FIG. 7B is a schematic diagram concerning the operation of a second spin transistor when V_{low} is input as Vᵢₙ in the third embodiment;

FIG. 7C is a schematic diagram concerning the operation of the first spin transistor when V_{high} is input as Vᵢₙ in the third embodiment;

FIG. 7D is a schematic diagram concerning the operation of the second spin transistor when V_{high} is input as Vᵢₙ in the third embodiment;

FIG. 8 is a schematic diagram of an integrated circuit according to a fourth embodiment;

FIG. 9 is a schematic diagram of an integrated circuit according to a fifth embodiment;

FIG. 10 is a schematic diagram of an integrated circuit according to a sixth embodiment;

FIG. 11 is a schematic diagram of an integrated circuit according to a seventh embodiment;

FIG. 12 is a schematic diagram of an integrated circuit according to an eighth embodiment;

FIG. 13A is a schematic diagram of a NAND circuit according to a ninth embodiment;

FIG. 13B is a logical operation table of the NAND circuit;

FIG. 14A is a schematic diagram of a NOR circuit according to a tenth embodiment; and

FIG. 14B is a logical operation table of the NOR circuit.

### DETAILED DESCRIPTION

In accordance with an embodiment, an integrated circuit includes a first spin transistor and a second spin transistor. The first spin transistor has a first channel length. The first spin transistor includes a first node and a second node apart from the first node. The second spin transistor is connected to the first transistor in series and has a second channel length different from the first channel length. The second spin transistor includes a third node and a fourth node apart from the third node. The second node and the fourth node are electrically connected to each other.

Embodiments will now be explained with reference to the accompanying drawings.

In a spin FET, a carrier moves through a 2 DEG channel. The precession of a spin of the carrier moving through the 2 DEG channel is controlled by Rashba effect. In the spin FET, when the direction of a spin deflection vector of the carrier at a drain end corresponds to the direction of a metallic spin band of a drain, a large number of carriers are conducted in a drain region. In the spin FET, when the direction of the spin deflection vector of the carrier corresponds to the direction of an insulator-like spin band, few carriers conduct the drain. It has heretofore been impossible to use the spin FET to produce a circuit equivalent to a conventional logical operation circuit comprising a MOSFET.

### Outline of Embodiments

An integrated circuit according to the embodiments comprises a circuit including a first spin transistor and a second spin transistor connected to the first spin transistor in series. The first spin transistor has a first channel length. The second spin transistor has a second channel length different from the first channel length.

### First Embodiment

(Configuration of Integrated Circuit)

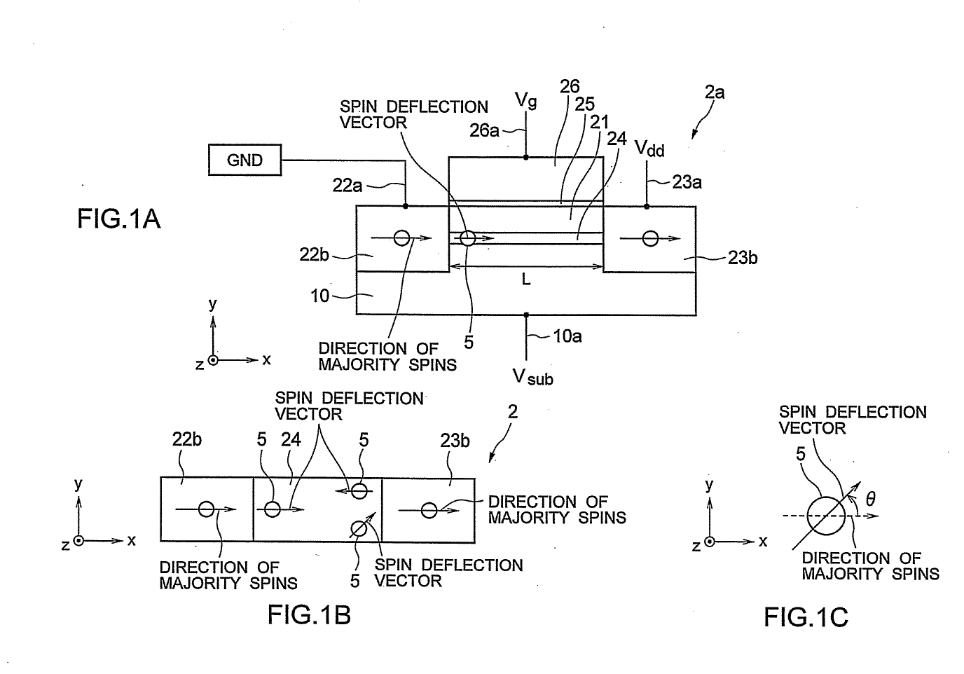

FIG. 1A is a schematic diagram of a spin transistor according to the first embodiment. FIG. 1B is a schematic diagram illustrating the basic operation of the spin transistor. FIG. 1C is a schematic diagram concerning a relative angle between the direction of majority spins of a magnetic body of a drain region and a spin deflection vector of an electron in a channel. An x-y-z coordinate system indicated in each of the accompanying drawings is, for example, a rectangular coordinate system. In particular, the direction of an effective magnetic field resulting from Rashba effect is defined as a z axis.

Hereinafter, arrows in a source region 22b and a drain region 23b of a spin transistor 2a indicate the directions of majority spins in each region. The direction of the majority spins indicates the direction of the angular momentum of the spins of majority electrons in the magnetic body.

Further, hereinafter, the arrow of an electron 5 indicates the deflection vector of the spin of the electron 5.

Still further, while the flow (spin current) of the electron 5 which is a carrier is mainly described below, it should be noted that the flow direction of the electron 5 which is a carrier is opposite to the flow direction of a current. Therefore, the electron (spin current) as a carrier travels from a low potential side (V_{low}) to a high potential side (V_{high}), whereas the current runs from the high potential side (V_{high}) to the low potential side (V_{low}). Moreover, in each spin transistor described below, the side connected to a power supply is used as a source region.

As shown in FIG. 1A, the spin transistor 2a is formed on, for example, a semiconductor substrate 10. The spin transistor 2a generally comprises, for example, a semiconductor layer 21, a source region 22b as a first node, a drain region 23b as a second node, a 2 DEG channel 24 as a first channel region, a gate insulating film 25, and a gate electrode 26 as a first gate electrode.

The semiconductor substrate 10 has a double heterostructure in which In₁₋ₓAlₓAs, In_{1-y}Ga_{y}As, and In₁₋ₓAlₓAs are stacked on an InP substrate in order by, for example, a molecular beam epitaxy method (MBE). While a large number of combinations of In₁₋ₓAlₓAs and In_{1-y}Ga_{y}As are possible depending on the mixing ratio, x=0.48 and y=0.47 in the present embodiment. Thus, hereinafter, unless otherwise stated, InAlAS indicates In_{0.52}Al_{0.48}As, and InGaAs indicates In_{0.53}Ga_{0.47}As. The spin transistor 2a has, for example, a terminal 10a under the gate electrode 26. A substrate potential V_{sub} is applied to the terminal 10a.

The semiconductor layer 21 uses, for example, InAlAs in the upper layer of the semiconductor substrate 10. The semiconductor layer 21 is, for example, Schottky-connected to the source region 22b and the drain region 23b. Here, in the 2 DEG channel 24, an InGaAs layer in the quantum well structure of InAlAs/InGaAs/InAlAs serves as a 2 DEG channel. When, for example, the semiconductor substrate 10 has a heterostructure in which InAlAs/InGaAs are stacked, the 2 DEG channel 24 is formed at an interface between InAlAs and InGaAs.

The source region 22b is formed, for example, by removing InAlAs, InGaAs, and part of InAlAs under InGaAs in the semiconductor substrate 10. The source region 22b has, for example, a terminal 22a. This terminal 22a is, for example, grounded (GND).

The drain region 23b is formed, for example, by removing InAlAs, InGaAs, and part of InAlAs under InGaAs in the semiconductor substrate 10. The drain region 23b has, for example, a terminal 23a. A power supply voltage V_{dd} (>0) is supplied to this terminal 23a from a power supply circuit.

The source region 22b and the drain region 23b are formed by use of, for example, a high spin deflection material. The high spin deflection material has a high spin polarizability (spin deflection factor) of electrons therein and can inject a large number of electrons having a uniform spin direction into the 2 DEG channel. A ferromagnetic metal and a half metal ferromagnetic body, for example, are used as the high spin deflection materials.

When the ferromagnetic metal is used as the high spin deflection material, Fe, Co, and Ni, for example, are used as the ferromagnetic metals. Here, the source region 22b and the drain region 23b are preferably made of, for example, a ferromagnetic body which is highly consistent with a group III-V semiconductor and which has a Curie temperature equal to or more than a room temperature (e.g. 300 K) and which has a wide band gap in the vicinity of a Fermi level E_{F} regarding the energy state of one spin. Suitable as such a ferromagnetic body is, for example, a half metal ferromagnetic body having a band structure in which the Fermi level E_{F} traverses one spin band (metallic spin band) and traverses the band gap in the other spin band (insulator-like spin band). That is, when the half metal ferromagnetic body having the above-mentioned band structure is used, a carrier having a theoretically 100% spin polarizability can be injected. This half metal ferromagnetic body comprises, for example, CrO₂, Fe₂O₃, Ga₁₋ₓMnₓAs, In₁₋ₓMnₓAs, Ge₁₋ₓMnₓ, LaSrMnO₄, or a Heuslar alloy. As the Heuslar alloy, Co₂MnAi, Co₂MnGe, Co₂MnSi, Co₂CrAl, Co₂FeAl, or CoMnGa, for example, is used.

The channel length of the 2 DEG channel 24 is, for example, L. The electron 5 travels through the 2 DEG channel 24 from the source region 22b to the drain region 23b.

Here, when the electron 5 travels to the drain region 23b through the 2 DEG channel 24, a spin orbit interaction called Rashba effect proportional to the intensity of an electric field in a y-axis direction emerges. As a result, an effective magnetic field is generated in a z-axis direction, and the spin in the electron 5 is influenced by this magnetic field. As shown in FIG. 1C, the electron 5 precesses around the z axis. The precession is performed in a direction in which a relative angle θ between a dotted line shown in FIG. 1C and an arrow indicating the direction of the deflection vector of the spin increases, that is, the precession is performed counterclockwise. The change of the relative angle θ caused by the precession is dependent on a Rashba parameter α and the channel length L. The Rashba parameter α here is an amount that indicates the magnitude of the Rashba effect. The Rashba parameter α also changes with a gate voltage V_{g}, and this change can be used to control the relative angle θ with the direction of the majority spins of an output node 23 in the vicinity of the drain region within the 2 DEG channel 24. Moreover, the Rashba parameter α is also dependent on the material of the 2 DEG channel 24. Therefore, the Rashba effect can be controlled by changing one of the layers that constitute the stack structure of the semiconductor substrate 10. The dotted line shown in FIG. 1C indicates the direction parallel to the direction of the majority spins of the output node 23.

As shown in FIG. 1B, for example, the electron 5 is injected into the 2 DEG channel 24 from the source region 22b in a spin-polarized condition, that is, in a condition in which the spin direction is uniform. The injected electron 5 precesses due to, for example, the Rashba effect, and penetrates or is reflected depending on the spin state when the electron 5 has reached the drain region 23b.

For example, as shown in FIG. 1B, when, the spin deflection vector is opposite to the direction of the majority spins of the drain region 23b, that is, is in the negative direction of the x axis in the drawing, the electron 5 is reflected at the border between the 2 DEG channel 24 and the drain region 23b. On the other hand, for example, as shown in FIG. 1B, when the spin deflection vector is not opposite to the direction of the majority spins of the drain region 23b, the electron 5 penetrates the border between the 2 DEG channel 24 and the drain region 23b. The penetration and reflection of the electron 5 at the border of the drain region 23b is described below in detail.

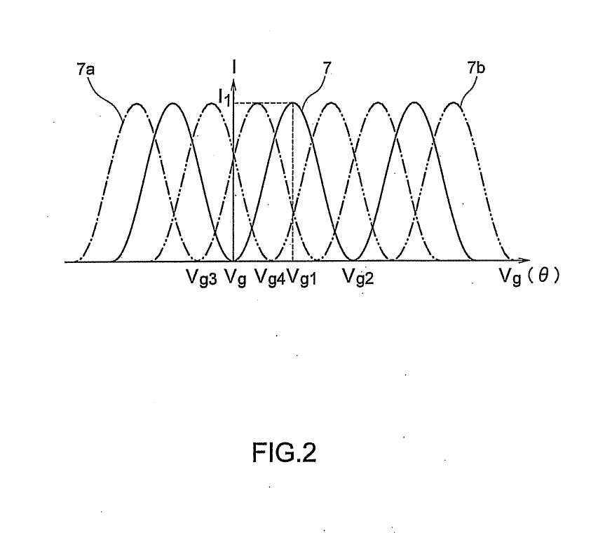

FIG. 2 is a current-voltage (I-V) curve of the spin transistor according to the first embodiment. In FIG. 2, the spin transistor 2a is given as an example, and the semiconductor substrate 10 is grounded. In FIG. 2, the vertical axis indicates the current, and the horizontal axis indicates the gate voltage V_{g}.

The relative angle θ and the penetration^{.} of the magnetic body by the electron traveling through the 2 DEG channel have the relation represented by Expression (1).

[Expression 1]

Penetration ∝ cos^{2 l (θ/}2) (1)

Here, the penetration means that the current runs through the spin transistor 2a. Thus, if I is the current running through the spin transistor 2a and no current runs when the gate voltage V_{g}=0, an I-V curve 7 indicated by a solid line in FIG. 2, for example, is obtained from Expression (1).

In the I-V curve 7, as shown in FIG. 2, a maximum current I₁ is obtained at a gate voltage V_{g1}, and no current is obtained at the gate voltage V_{g} or V_{g2}. That is, the electron 5 precesses π when the gate voltage V_{g} or the gate voltage V_{g2} is applied to the 2 DEG channel 24. In the following embodiments, the channel length at this point is L.

Here, the V_{g} dependence of the Rashba parameter α that is experimentally observed is described by linearization in a given limited region. First, it should be understood that the Rashba parameter α is dependent on the gate voltage V_{g} (α(V_{g})). In this case, an off voltage V_{g}^{off} provided by Expression (2).

$$\begin{matrix}[ Expression 2 ] & \\ α ( {V}_{g}^{off} ) = \frac{{ℏ}^{2} π}{2 {m}^{*} L} & ( 2 )\end{matrix}$$

: Converted Plank's constant

m*: Effective mass of electron

In accordance with Expression (2), when the same gate bias is applied to the channel, the value of the Rashba parameter α is equal to the value of Expression (2) even if the channel length is n times. Therefore, the spin deflection vector of the carrier turns rot when the carrier travels a distance L through the channel.

Thus, the relation in Expression (3) is derived.

$$\begin{matrix}[ Expression 3 ] & \\ {V}_{g} = \frac{{ℏ}^{2} π}{2 {m}^{*} L} ( \frac{1}{n} - 1 ) & ( 3 )\end{matrix}$$

An I-V curve 7a indicated by a one-dot chain line in FIG. 2, for example, is obtained by Expression (3). This I-V curve 7a is equivalent to the I-V curve 7 that is moved to the left in the sheet of FIG. 2. In this case, the gate voltage that brings a current I to zero-moves from V_{g} to V_{g3} (<0).

Similarly, when the same gate bias is applied to the channel and the channel length is made 1/n times, the spin deflection vector of the carrier turns by π/n. Thus, the relation in Expression (4) is derived.

$$\begin{matrix}[ Expression 4 ] & \\ {V}_{g} = \frac{{ℏ}^{2} π}{2 {m}^{*} L} ( n - 1 ) & ( 4 )\end{matrix}$$

An I-V curve 7b indicated by a two-dot chain line in FIG. 2, for example, is obtained by Expression (4). This I-V curve 7b is equivalent to the I-V curve 7 that is moved to the right in the sheet of FIG. 2. In this case, the gate voltage that brings the current I to zero moves from V_{g} to V_{g4} (>0).

That is, the gate voltage V_{g} changes the off voltage that brings the current I to zero if the channel length of the spin transistor is changed. Thus, the spin transistors different in channel length can be used to configure an integrated circuit in which one spin transistor is off and the other spin transistor is on when V_{g}=0. Accordingly, the on-current of the spin transistor can be easily estimated. This proves that an off-current can be determined within the values of the Rashba parameter α by changing the channel length.

An integrated circuit that uses the above-mentioned spin transistor is described below. It is to be noted that parts equivalent in configuration and function to those in the above-mentioned spin transistor 2a are provided with the same reference signs and repeated explanations are not described.

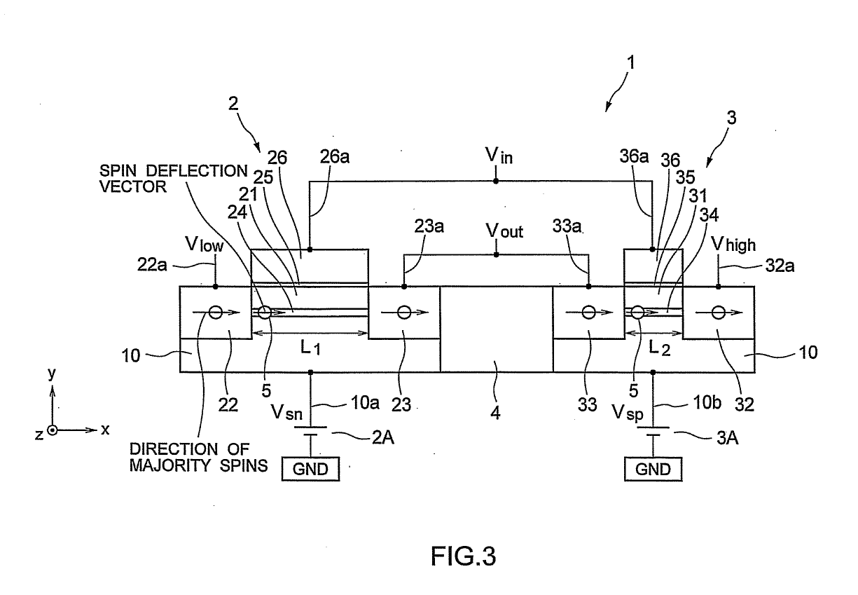

FIG. 3 is a schematic diagram of an inverter circuit that uses two spin transistors according to the first embodiment.

As shown in FIG. 3, an integrated circuit 1 is, for example, a logical operation circuit that uses first and second two spin transistors 2 and 3 different in channel length. This logical operation circuit is, for example, an inverter circuit. In the integrated circuit 1, an element isolation region 4 for electrically isolating the first and second spin transistors 2 and 3, for example, is formed between the first and second spin transistors 2 and 3. This element isolation region 4 comprises, for example, SiO₂.

As shown in FIG. 3, the first spin transistor 2 is formed on, for example, a semiconductor substrate 10. The first spin transistor 2 generally comprises, for example, a semiconductor layer 21, a V_{low} node 22 as a first node, an output node 23 as a second node, a 2 DEG channel 24 as a first channel region, a gate insulating film 25, and a gate electrode 26 as a first gate electrode.

The V_{low} node 22 is formed, for example, by removing InAlAs, InGaAs, and part of InAlAs under InGaAs in the semiconductor substrate 10. The V_{low} node 22 has, for example, a terminal 22a. For example, a power supply voltage V_{low} is supplied to this terminal 22a from a power supply circuit.

The first spin transistor 2 has, for example, a terminal 10a under the gate electrode 26. A substrate potential Vₛₙ generated by a power supply 2A which is grounded at one end is applied to the terminal 10a.

The output node 23 is formed, for example, by removing InAlAs, InGaAs, and part of InAlAs under InGaAs in the semiconductor substrate 10. The output node 23 has, for example, a terminal 23a. This terminal 23a is connected to a terminal 33a of a later-described output node 33 of the second spin transistor 3. The integrated circuit 1 is a circuit in which the first spin transistor 2 and the second spin transistor 3 are connected in series between the power supply voltage V_{low} and a power supply voltage V_{high}.

The V_{low} node 22 and the output node 23 are formed by use of, for example, a high spin deflection material. A ferromagnetic metal and a half metal ferromagnetic body, for example, are used as the high spin deflection materials.

A terminal 26a of the gate electrode 26 is connected to, for example, a later-described terminal 36a of a second gate electrode 36 of the second spin transistor 3. A digital signal Vᵢₙ is input to the terminal 26a.

As shown in FIG. 3, the second spin transistor 3 is formed on, for example, the semiconductor substrate 10. The second spin transistor 3 generally comprises, for example, a semiconductor layer 31, a V_{high} node 32 as a third node, an output node 33 as a fourth node, a 2 DEG channel 34 as a second channel region, a gate insulating film 35, and a gate electrode 36 as a second gate electrode.

The second spin transistor 3 has, for example, a terminal 10b under the gate electrode 36. A substrate potential Vₛₚ generated by a power supply 3A which is grounded at one end is applied to the terminal 10a.

The semiconductor layer 31 is substantially the same as, for example, the semiconductor layer 21 of the first spin transistor 2. The semiconductor layer 31 is, for example, Schottky-connected to the V_{high} node 32 and the output node 33. Here, in the 2 DEG channel 34, an InGaAs layer in the quantum well structure of InAlAs/InGaAs/InAlAs serves as a 2 DEG channel. When, for example, the semiconductor substrate 10 has a heterostructure in which InAlAs/InGaAs are stacked, the 2 DEG channel 34 is formed at an interface between InAlAs and InGaAs.

The V_{high} node 32 and the output node 33 are formed, for example, by removing InAlAs, InGaAs, and part of InAlAs under InGaAs in the semiconductor substrate 10. The V_{high} node 32 and the output node 33 are formed by using, for example, the same material as that of the V_{low} node 22 and the output node 23 of the first spin transistor 2.

The V_{high} node 32 has, for example, a terminal 32a. The power supply voltage V_{high} is supplied to this terminal 32a from a power supply circuit. The output node 33 has, for example, the terminal 33a.

The channel length of the 2 DEG channel 34 as a second channel length is, for example, L₂. An electron 5 travels through the 2 DEG channel 34 from the output node 33 to the V_{high} node 32.

The gate insulating film 35 is formed on the semiconductor layer 31. The gate insulating film 35 comprises, for example, SiO₂.

The gate electrode 36 is formed on, for example, the gate insulating film 35. The gate electrode 36 is made of, for example, the same material as the gate electrode 26 of the first spin transistor 2. The gate electrode 36 has, for example, the terminal 36a. A digital signal Vᵢₙ is input to the terminal 36a.

Here, the integrated circuit 1 is an inverter circuit which outputs the digital signal V_{high} as Vₒᵤₜ when the digital signal V_{low} is input as Vᵢₙ and which outputs the digital signal V_{low} as Vₒᵤₜ when the digital signal V_{high} is input as Vᵢₙ. Now, the substrate potentials Vₛₙ and Vₛₚ as well as V_{low} and V_{high} are described.

The following four expressions are obtained

[Expression 5]

V_{low}=Vₛₙ+Vₙ^{off} (5)

[Expression 6]

V_{low}=Vₛₚ+Vₚ^{on} (₆)

[Expression 7]

V_{high}=Vₛₙ+¹³Vₙ^{on} (7)

[Expression 8]

V_{high}=Vₛₚ+Vₚ^{off} (8)

wherein Vₙ^{on} is a voltage that can switch on the first spin transistor 2, Vₙ^{off} is a voltage that can switch off the first spin transistor 2, Vₚ^{on} is a voltage that can switch on the second spin transistor 3, and Vₚ^{off} is a voltage that can switch off the second spin transistor 3.

Expression (5) is an expression to find Vₛₙ and Vₙ^{off} for switching off the first spin transistor 2 when V_{low} is input as Vᵢₙ. Expression (6) is an expression to find Vₛₚ and Vₚ for switching on the second spin transistor 3 when V_{low} is input as Vᵢₙ. Expression (7) is an expression to find Vₛₙ and Vₙ^{on} for switching on the first spin transistor 2 when V_{high} is input as Vᵢₙ. Expression (8) is an expression to find Vₛₚ and Vₚ^{off} for switching off the second spin transistor 3 when V_{high} is input as Vᵢₙ. When given channel lengths are selected for both the transistors that constitute the inverter circuit in accordance with Expressions (5) to (8), an off-potential is determined by, for example, Expression (2). Therefore, if the substrate potential is applied, the power supply voltages V_{low} and V_{high} of the inverter circuit are immediately determined, and an on-potential is also determined at the same time. That is, the structure of the inverter circuit of the spin transistor is completely fulfilled by Expressions (5) to (8).

The operation of the integrated circuit according to the present embodiment is described below.

(Operation)

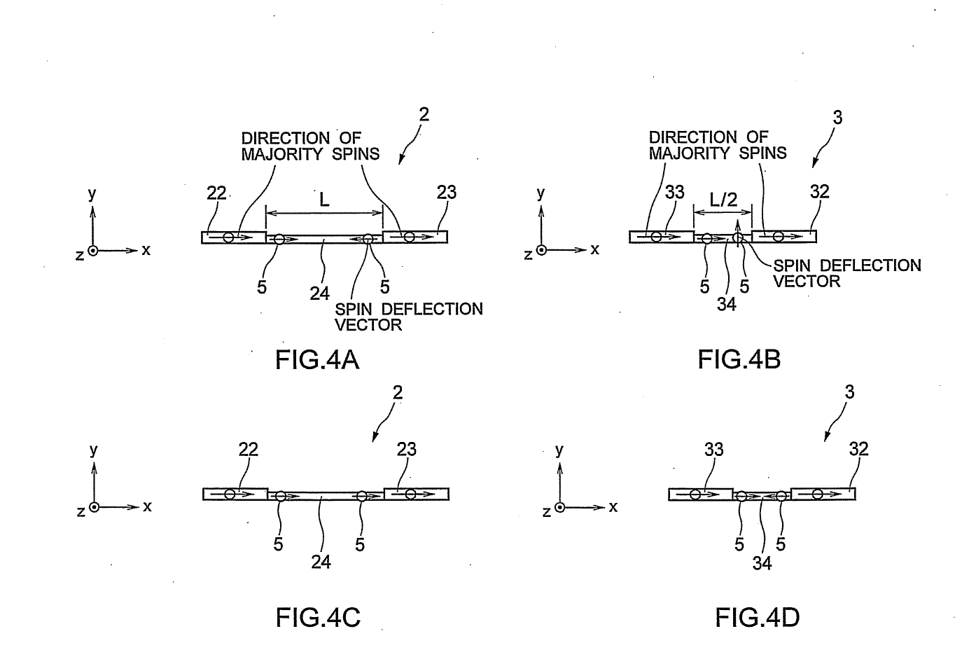

FIG. 4A is a schematic diagram concerning the operation of the first spin transistor when V_{low} is input as Vᵢₙ according to the first embodiment. FIG. 4B is a schematic diagram concerning the operation of the second spin transistor when V_{low} is input as Vᵢₙ. FIG. 4C is a schematic diagram concerning the operation of the first spin transistor when V_{high} is input as Vᵢₙ. FIG. 4D is a schematic diagram concerning the operation of the second spin transistor when V_{high} is input as Vᵢₙ. Hereinafter, a channel length L₁ of the first spin transistor 2 is L, and a channel length L₂ of the second spin transistor 3 is L/2. First, a case in which Vᵢₙ=V_{low} is described.

(When Vᵢₙ=V_{low})

First, V_{low} is input as Vᵢₙ to the gate electrode 26 of the first spin transistor 2 and to the gate electrode 36 of the second spin transistor 3.

As shown in FIG. 4A, a spin-polarized electron 5 is injected into the 2 DEG channel 24 from the V_{low} node 22 of the first spin transistor 2.

As shown in FIG. 4A, this electron 5 precesses, for example, at an angle π around the z axis due to an effective magnetic field in the 2 DEG channel 24, and reaches the border between the 2 DEG channel 24 and the output node 23.

The electron 5 which has reached the border has a spin direction that differs by an angle π from the direction of majority electron spins of the output node 23, and is therefore reflected at the border.

On the other hand, as shown in FIG. 4B, a spin-polarized electron 5 is injected into the 2 DEG channel 34 from the output node 33 of the second spin transistor 3.

As shown in FIG. 4B, this electron 5 precesses, for example, at an angle π/2 around the z axis due to an effective magnetic field in the 2 DEG channel 34, and reaches the border between the 2 DEG channel 34 and the V_{high} node 32. The angle π/2 of the precession is attributed to the fact that the channel length L₂ of the second spin transistor 3 is half the channel length L₁ of the first spin transistor 2.

The electron 5 which has reached the border has a spin direction that differs by an angle π/2 from the direction of majority spins of the V_{high} node 32, and therefore penetrates the border.

Accordingly, in the integrated circuit 1, when Vᵢₙ=V_{low}, no current runs through the first spin transistor 2, and a current runs through the second spin transistor 3, so that V_{high} input to the V_{high} node 32 of the second spin transistor 3 is output from Vₒᵤₜ.

(When Vᵢₙ=V_{high})

First, V_{high} is input as Vᵢₙ to the gate electrode 26 of the first spin transistor 2 and to the gate electrode 36 of the second spin transistor 3.

As shown in FIG. 4C, a spin-polarized electron 5 is injected into the 2 DEG channel 24 from the V_{low} node 22 of the first spin transistor 2.

As shown in FIG. 4C, this electron 5 precesses, for example, at an angle 2π around the z axis due to a magnetic field in the 2 DEG channel 24, and reaches the border between the 2 DEG channel 24 and the output node 23.

The electron 5 which has reached the border has a spin direction that differs by an angle 2π from the direction of majority spins of the output node 23, and therefore penetrates the border.

On the other hand, as shown in FIG. 4D, a spin-polarized electron 5 is injected into the 2 DEG channel 34 from the output node 33 of the second spin transistor 3.

As shown in FIG. 4D, this electron 5 precesses, for example, at an angle π around the z axis due to an effective magnetic field in the 2 DEG channel 34, and reaches the border between the 2 DEG channel 34 and the V_{high} node 32.

The electron 5 which has reached the border has a spin direction that differs by an angle π from the direction of majority spins of the V_{high} node 32, and is therefore reflected at the border.

Accordingly, in the integrated circuit 1, when Vᵢₙ=V_{high}, a current runs through the first spin transistor 2, and no current runs through the second spin transistor 3, so that V_{low} input to the V_{low} node 22 of the first spin transistor 2 is output from Vₒᵤₜ.

Thus, the integrated circuit 1 comprises an inverter circuit which outputs V_{high} as Vₒᵤₜ when V_{low} is input as Vᵢₙ and which outputs V_{low} as Vₒᵤₜ when V_{high} is input as Vᵢₙ.

### Advantages of the First Embodiment

The integrated circuit 1 according to the first embodiment comprises the spin transistors different in channel length that are connected in series. Therefore, as compared with an inverter circuit which comprises a complementary metal oxide semiconductor (CMOS) transistor, there is no need for separate p-type and n-type transistors, leading to fewer manufacturing processes and reduced manufacturing costs.

### Second Embodiment

The second embodiment is different from the first embodiment in that V_{low}=Vₛₙ=Vₛₚ. It is to be noted that in the following embodiments, parts equivalent in function and configuration to those in the first embodiment are provided with the same reference signs and are not described.

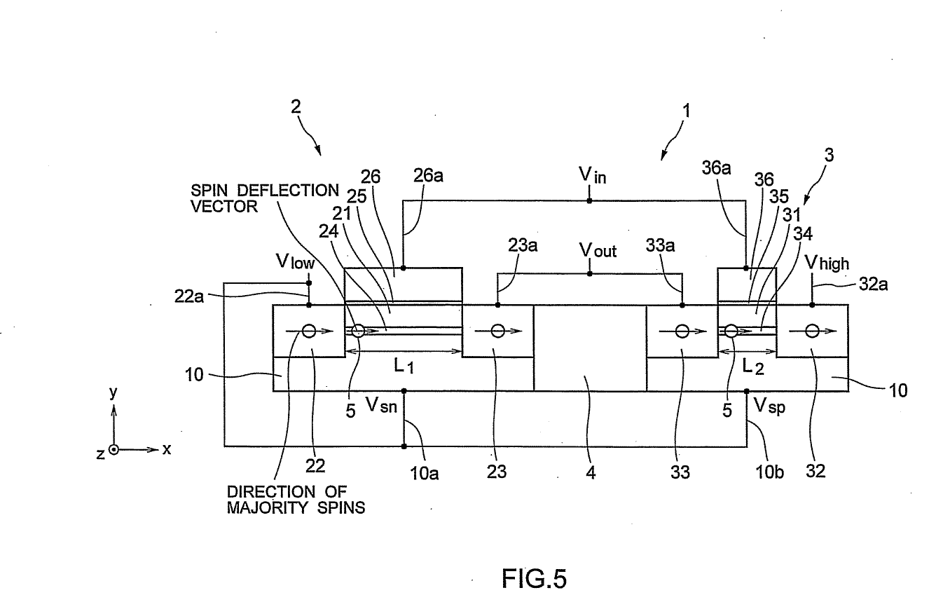

FIG. 5 is a schematic diagram of an integrated circuit according to the second embodiment. As shown in FIG. 5, in an integrated circuit 1 according to the present embodiment, a terminal 10a and a terminal 10b provided in a semiconductor substrate 10 are connected to each other, and are also connected to a terminal 22a of a V_{low} node 22 of a first spin transistor 2. Thus, V_{low}=Vₛₙ=Vₛₚ is satisfied.

The use of V_{low}=Vₛₙ=Vₛₚ allows the following expressions to be derived from Expressions (5) to (8).

[Expression 9]

Vₙ^{off}=Vₚ^{on}=0 (9)

[Expression 10]

Vₙ^{on}=Vₚ^{off}=V_{high}−V_{low} (10)

From Expressions (9) and (10), digital signals V_{low} and V_{high}, substrate potentials Vₛₙ and Vₛₚ, and voltages Vₙ^{on}, Vₙ^{off}, Vₚ^{on}, and Vₚ^{off} corresponding to channel lengths are found.

The integrated circuit 1 according to the second embodiment is similar to the integrated circuit 1 according to the first embodiment except that the terminals 10a, 10b, and 22a are connected. Thus, the integrated circuit 1 according to the present embodiment comprises an inverter circuit which outputs V_{high} as Vₒᵤₜ when V_{low} is input as Vᵢₙ and which outputs V_{low} as Vₒᵤₜ when V_{high} is input as Vᵢₙ.

### Advantages of the Second Embodiment

In the integrated circuit 1 according to the second embodiment, the substrate potentials Vₛₙ and Vₛₚ are the same as the potential of the V_{low} node 22 of the first spin transistor 2. Therefore, as compared with an inverter circuit which comprises a CMOS transistor, the configuration is simpler, and manufacturing costs are reduced.

### Third Embodiment

The third embodiment is different from the embodiments described above in that a channel length L₂ of a second spin transistor 3 is n times a channel length L₁ of a first spin transistor 2 and that V_{high}=Vₛₙ=Vₛₚ is satisfied.

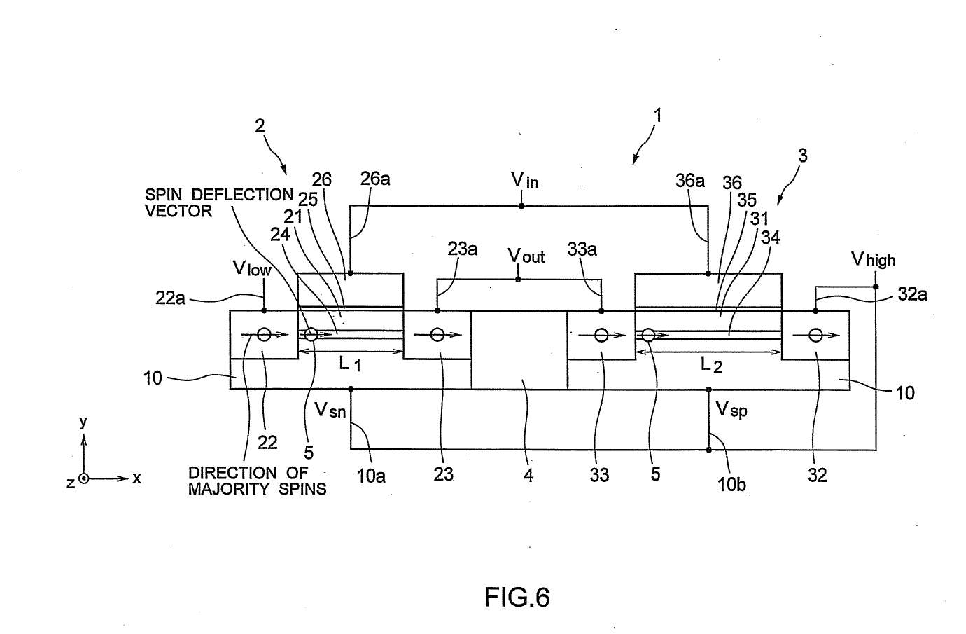

FIG. 6 is a schematic diagram of an integrated circuit according to the third embodiment. As shown in FIG. 6, in an integrated circuit 1 according to the present embodiment, terminals 10a and 10b are connected to a terminal 32a of a V_{high} node 32 of the second spin transistor 3. Thus, V_{high}=Vₛₙ=Vₛₚ is satisfied.

The use of V_{high}=Vₛₙ=Vₛₚ allows the following expressions to be derived from Expressions (5) to (8).

[Expression 11]

Vₙ^{off}=Vₚ^{on}=−(V_{high}−V_{low}) (11)

[Expression 12]

Vₙ^{on}=Vₚ^{off}=0 (12)

From Expressions (11) and (12), digital signals V_{low} and V_{high}, substrate potentials Vₛₙ and Vₛₚ, and voltages Vₙ^{on}, Vₙ^{off}, Vₚ^{on}, and Vₚ^{off} corresponding to channel lengths are found.

Moreover, a channel length L₂ of the second spin transistor 3 is n times a channel length L₁ of the first spin transistor 2.

The operation of the integrated circuit 1 according to the present embodiment is described below.

(Operation)

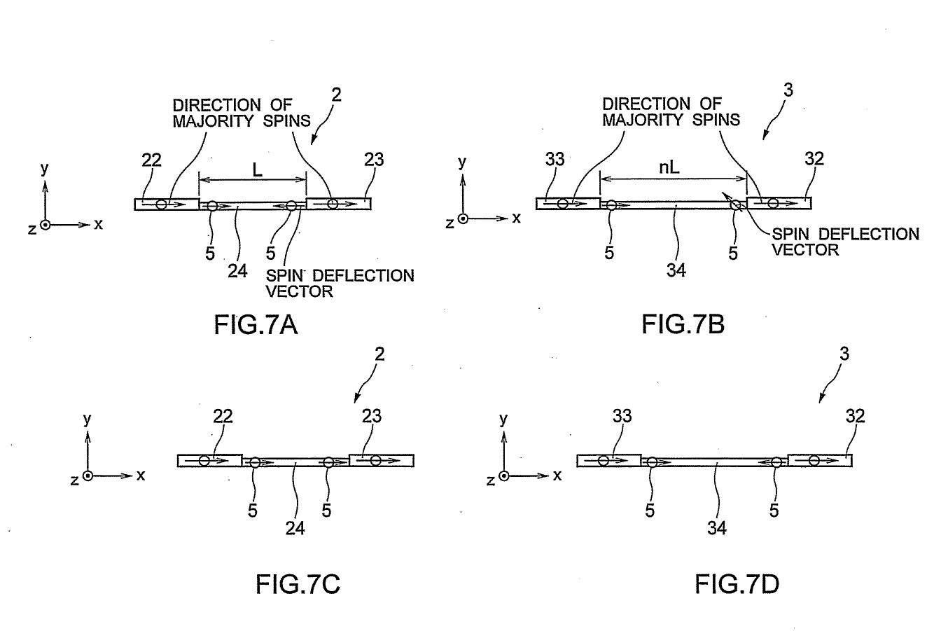

FIG. 7A is a schematic diagram concerning the operation of the first spin transistor when V_{low} is input as Vᵢₙ according to the third embodiment. FIG. 7B is a schematic diagram concerning the operation of the second spin transistor when V₁₀ is input as Vᵢₙ. FIG. 7C is a schematic diagram concerning the operation of the first spin transistor when V_{high} is input as Vᵢₙ. FIG. 7D is a schematic diagram concerning the operation of the second spin transistor when V_{high} is input as Vᵢₙ. Hereinafter, the channel length L₁ of the first spin transistor 2 is L, and the channel length L₂ of the second spin transistor 3 is nL. However, assumption is made that 1<n<3 for simplicity. First, a case in which Vᵢₙ=V_{low} is described.

(When Vᵢₙ=V_{low})

First, V_{low} is input as Vᵢₙ to a gate electrode 26 of the first spin transistor 2 and to a gate electrode 36 of the second spin transistor 3.

As shown in FIG. 7A, a spin-polarized electron 5 is injected into a 2 DEG channel 24 from a V_{low} node 22 of the first spin transistor 2.

As shown in FIG. 7A, this electron 5 precesses, for example, at an angle π around the z axis due to an effective magnetic field in the 2 DEG channel 24, and reaches the border between the 2 DEG channel 24 and an output node 23. The electron 5 which has reached the border has a spin direction that differs by an angle π from the direction of majority spins of the output node 23, and is therefore reflected at the border.

On the other hand, as shown in FIG. 7B, a spin-polarized electron 5 is injected into a 2 DEG channel 34 from an output, node 33 of the second spin transistor 3.

As shown in FIG. 7B, 1<n<3, so that this electron 5 precesses, for example, within π<θ<3π around the z axis due to an effective magnetic field in the 2 DEG channel 34, and reaches the border between the 2 DEG channel 34 and the V_{high} node 32.

The electron 5 which has reached the border has a spin direction that differs from the direction of majority spins of the V_{high} node 32 within π<θ<3π, and therefore penetrates the border.

Accordingly, in the integrated circuit 1, when Vᵢₙ=V_{low}, no current runs through the first spin transistor 2, and a current runs through the second spin transistor 3, so that V_{high} input to the output node 33 of the second spin transistor 3 is output from Vₒᵤₜ.

(When Vᵢₙ=V_{high})

First, V_{high} is input as Vᵢₙ to the gate electrode 26 of the first spin transistor 2 and to the gate electrode 36 of the second spin transistor 3.

As shown in FIG. 7C, a spin-polarized electron 5 is injected into the 2 DEG channel 24 from the V_{low} node 22 of the first spin transistor 2.

As shown in FIG. 7C, this electron 5 precesses, for example, at an angle 2π around the z axis due to an effective magnetic field in the 2 DEG channel 24, and reaches the border between the 2 DEG channel 24 and the output node 23.

The electron 5 which has reached the border has a spin direction that differs by an angle 2π from the direction of majority electron spins of the output node 23, and therefore penetrates the border.

On the other hand, as shown in FIG. 7D, a spin-polarized electron 5 is injected into the 2 DEG channel 34 from the output node 33 of the second spin transistor 3.

As shown in FIG. 7D, this electron 5 precesses, for example, at an angle 3π around the z axis due to an effective magnetic field in the 2 DEG channel 34, and reaches the border between the 2 DEG channel 34 and the V_{high} node 32.

The electron 5 which has reached the border has a spin direction that differs by an angle 3π from the direction of majority spins of the V_{high} node 32, and is therefore reflected at the border.

Accordingly, in the integrated circuit 1, when Vᵢₙ=V_{high}, a current runs through the first spin transistor 2, and no current runs through the second spin transistor 3, so that V_{low} input to the V_{low} node 22 of the first spin transistor 2 is output from Vₒᵤₜ.

Thus, the integrated circuit 1 comprises an inverter circuit which outputs V_{high} as Vₒᵤₜ when V_{low} is input as Vᵢₙ and which outputs V_{low} as Vₒᵤₜ when V_{high} is input as Vᵢₙ.

### Advantages of the Third Embodiment

In the integrated circuit 1 according to the third embodiment, the substrate potentials Vₛₙ and Vₛₚ are the same as the potential of the V_{high} node 32 of the second spin transistor 3. Therefore, as compared with an inverter circuit which comprises a CMOS transistor, the configuration is simpler, and manufacturing costs are reduced.

### Fourth Embodiment

The fourth embodiment is different from the embodiments described above in that Vₛₙ=V_{high} and Vₛₚ=V_{low}.

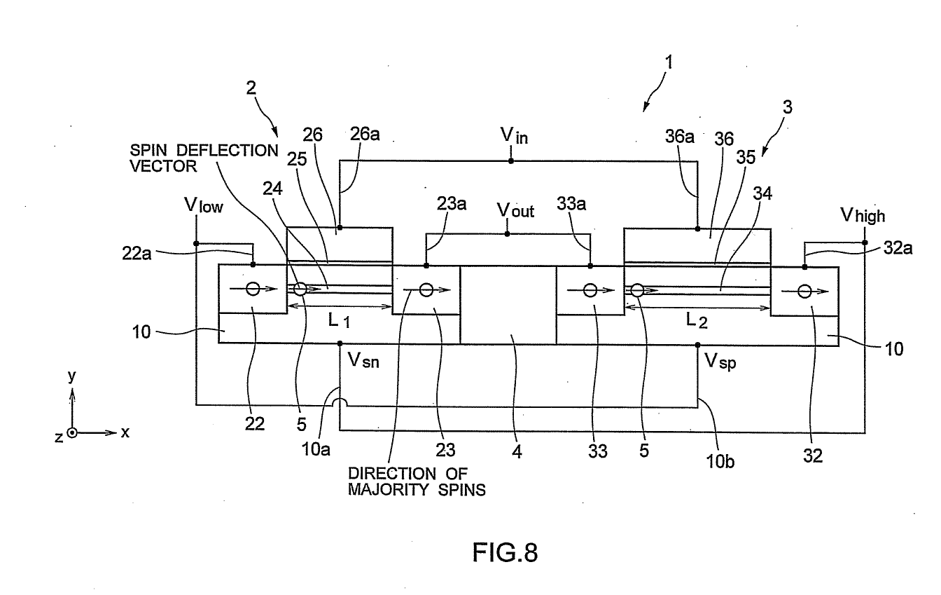

FIG. 8 is a schematic diagram of an integrated circuit according to the fourth embodiment. In an integrated circuit 1, a terminal 10a is connected to a terminal 32a of a V_{high} node 32 of a second spin transistor 3. Moreover, in the integrated circuit 1, a terminal 10b is connected to a terminal 22a of a V_{low} node 22 of a first spin transistor 2. Thus, Vₛₙ=V_{high} and Vₛₚ=V_{low} are satisfied. Channel lengths L₁ and L₂ are the same as those in the third embodiment. However, assumption is made that 1<n<3 for simplicity.

The use of Vₛₙ=V_{high} and Vₛₚ=V_{low} allows the following expressions to be derived from Expressions (5) to (8).

[Expression 13]

−Vₙ^{off}=Vₚ^{off}=−(V_{high}−V_{low}) (13)

[Expression 14]

Vₚ^{on}=Vₙ^{on}=0 (14)

Expression (13) shows that off-states of the first and second spin transistors 2 and 3 are produced by the difference of potentials equal in absolute value. From Expressions (13) and (14), digital signals V_{low} and V_{high}, substrate potentials Vₛₙ and Vₛₚ, and voltages Vₙ^{on}, Vₙ^{off}, Vₚ^{on}, and Vₚ^{off} corresponding to channel lengths are found.

The operation of the integrated circuit 1 according to the present embodiment is similar to that in the third embodiment because the channel lengths L₁ and L₂ are the same as those in the third embodiment. Thus, the integrated circuit 1 according to the present embodiment comprises an inverter circuit which outputs V_{high} as Vₒᵤₜ when V_{low} is input as Vᵢₙ and which outputs V_{low} as Vₒᵤₜ when V_{high} is input as Vᵢₙ.

### Advantages of the Fourth Embodiment

The integrated circuit 1 according to the fourth embodiment is operated by voltages equal in absolute value (−Vₙ^{off}=Vₚ^{off}). Therefore, as compared with an inverter circuit which comprises a CMOS transistor, uneven on-current density can be reduced.

### Fifth Embodiment

The fifth embodiment is different from the embodiments described above in that a first spin transistor 2 and a second spin transistor 3 share a drain region.

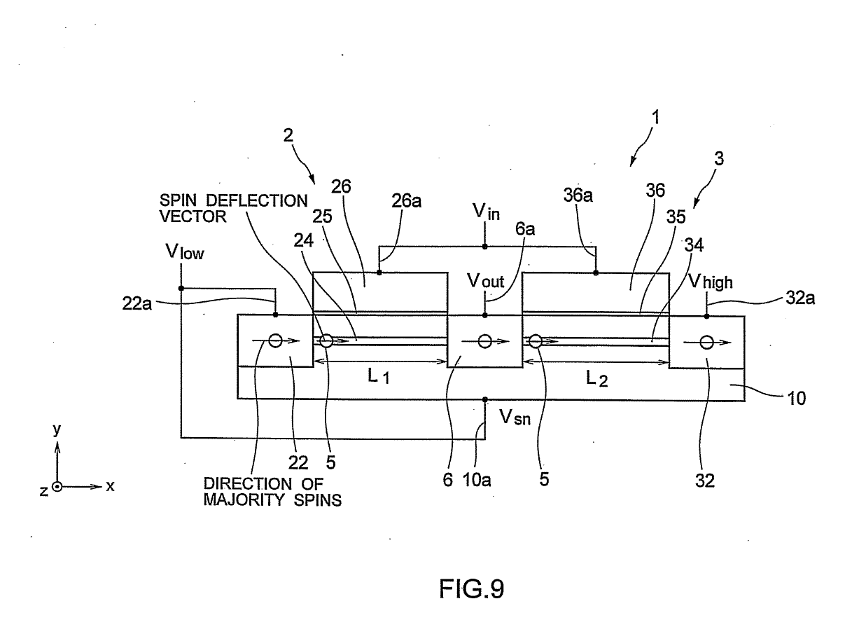

FIG. 9 is a schematic diagram of an integrated circuit according to the fifth embodiment. As shown in FIG. 9, in an integrated circuit 1, substrate potentials Vₛₙ and Vₛₚ are the same, so that the element isolation region 4 in the embodiments described above can be omitted. Thus, as shown in FIG. 9, the integrated circuit 1 comprises a drain region 6 which is a combination of the drain region of the first spin transistor 2 and the drain region of the second spin transistor 3.

This drain region 6 is made of, for example, the same material as V_{low} nodes 22 and 32.

The output node 6 has, for example, a terminal 6a. This terminal 6a outputs Vₒᵤₜ.

A semiconductor substrate 10 has a terminal 10a. This terminal 10a is connected to a terminal 22a of the V_{low} node 22 of the first spin transistor 2. Thus, V_{low}=Vₛₙ=Vₛₚ is satisfied.

The use of V_{low}=Vₛₙ=Vₛₚ allows Expressions (9) and (10) to be derived. From Expressions (9) and (10), digital signals V_{low} and V_{high}, substrate potentials Vₛₙ and Vₛₚ, and voltages Vₙ^{on}, Vₙ^{off}, Vₚ^{on}, and Vₚ^{off} corresponding to channel lengths are found.

The operation of the integrated circuit 1 according to the present embodiment is described below.

(Operation)

Hereinafter, channel lengths L₁ and L₂ are the same as those in the third embodiment. However, assumption is made that 1<n<3 for simplicity. First, a case in which Vᵢₙ=V_{low} is described.

(When Vᵢₙ=V_{low})

First, V_{low} is input as Vᵢₙ to a gate electrode 26 of the first spin transistor 2 and to a gate electrode 36 of the second spin transistor 3.

A spin-polarized electron 5 is injected into a 2 DEG channel 24 from the V_{low} node 22 of the first spin transistor 2.

This electron 5 precesses, for example, at an angle π around the z axis due to an effective magnetic field in the 2 DEG channel 24, and reaches the border between the 2 DEG channel 24 and the output node 6.

The electron 5 which has reached the border has a spin direction that differs by an angle π from the direction of majority spins of the output node 6, and is therefore reflected at the border.

On the other hand, a spin-polarized electron 5 is injected into a 2 DEG channel 34 from the output node 6 of the second spin transistor 3.

This electron 5 precesses, for example, within π<θ<3π around the z axis due to an effective magnetic field in the 2 DEG channel 34, and reaches the border between the 2 DEG channel 34 and the V_{high} node 32.

The electron 5 which has reached the border has a spin direction that differs from the direction of majority spins of the V_{high} node 32 within π<θ<3π, and therefore penetrates the border.

Accordingly, in the integrated circuit 1, when Vᵢₙ=V_{low}, no current runs through the first spin transistor 2, and a current runs through the second spin transistor 3, so that V_{high} input to the output node 6 is output from Vₒᵤₜ.

(When Vᵢₙ=V_{high})

First, V_{high} is input as Vᵢₙ to the gate electrode 26 of the first spin transistor 2 and to the gate electrode 36 of the second spin transistor 3.

A spin-polarized electron 5 is injected into the 2 DEG channel 24 from the V_{low} node 22 of the first spin transistor 2.

This electron 5 precesses, for example, at an angle 2π around the z axis due to an effective magnetic field in the 2 DEG channel 24, and reaches the border between the 2 DEG channel 24 and the output node 6.

The electron 5 which has reached the border has a spin direction that differs by an angle 2π from the direction of majority spins of the output node 6, and therefore penetrates the border.

On the other hand, a spin-polarized electron 5 is injected into the 2 DEG channel 34 from the output node 6.

This electron 5 precesses, for example, at an angle 3π around the z axis due to an effective magnetic field in the 2 DEG channel 34, and reaches the border between the 2 DEG channel 34 and the V_{high} node 32.

The electron 5 which has reached the border has a spin direction that differs by an angle 3π from the direction of majority spins of the V_{high} node 32, and is therefore reflected at the border.

Accordingly, in the integrated circuit 1, when Vᵢₙ=V_{high}, a current runs through the first spin transistor 2, and no current runs through the second spin transistor 3, so that V_{low} input to the V_{low} node 22 of the first spin transistor 2 is output from Vₒᵤₜ.

Thus, the integrated circuit 1 comprises an inverter circuit which outputs V_{high} as Vₒᵤₜ when V_{low} is input as Vᵢₙ and which outputs V_{low} as Vₒᵤₜ when V_{high} is input as Vᵢₙ.

### Advantages of the Fifth Embodiment

The integrated circuit 1 according to the fifth embodiment needs no element isolation region because the substrate potentials Vₛₙ and Vₛₚ are equal, and can therefore be placed in a smaller area as compared with an integrated circuit which requires an element isolation region.

### Sixth Embodiment

The sixth embodiment is different from the fifth embodiment in that substrate potentials are equal to the potential of a V_{high} node 32 of a second spin transistor 3.

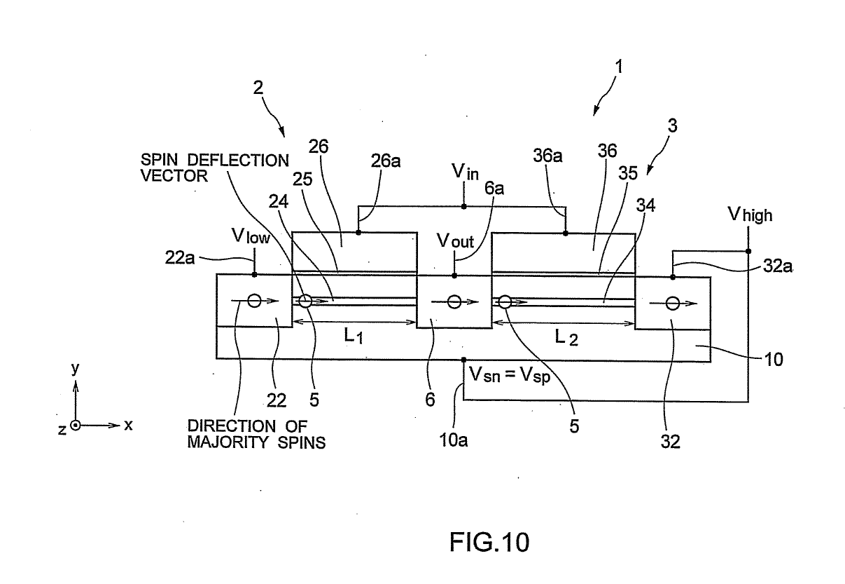

FIG. 10 is a schematic diagram of an integrated circuit according to the sixth embodiment. As shown in FIG. 10, in the integrated circuit 1, a terminal 10a is connected to the terminal 32a of the V_{high} node 32 of the second spin transistor 3. Thus, Vₛₙ=Vₛₚ=V_{high}. Accordingly, from Expressions (10) and (11), digital signals V_{low} and V_{high}, substrate potentials Vₛₙ and Vₛₚ, and voltages Vₙ^{on}, Vₙ^{off}, Vₚ^{on}, and Vₚ^{off} corresponding to channel lengths are found.

The operation of the integrated circuit 1 according to the present embodiment is described below.

(When Vᵢₙ=V_{low})

First, V_{low} is input as Vᵢₙ to a gate electrode 26 of the first spin transistor 2 and a gate electrode 36 of the second spin transistor 3.

A spin-polarized electron 5 is injected into a 2 DEG channel 24 from a V_{low} node 22 of the first spin transistor 2.

This electron 5 precesses, for example, at an angle π around the z axis due to an effective magnetic field in the 2 DEG channel 24, and reaches the border between the 2 DEG channel 24 and an output node 6.

The electron 5 which has reached the border has a spin direction that differs by an angle π from the direction of majority spins of the output node 6, and is therefore reflected at the border.

On the other hand, a spin-polarized electron 5 is injected into a 2 DEG channel 34 from the output node 6 of the second spin transistor 3.

This electron 5 precesses, for example, within π<θ<3π around the z axis due to an effective magnetic field in the 2 DEG channel 34, and reaches the border between the 2 DEG channel 34 and the V_{high} node 32.

The electron 5 which has reached the border has a spin direction that differs from the direction of majority spins of the V_{high} node 32 within π<θ<3π, and therefore penetrates the border.

Accordingly, in the integrated circuit 1, when Vᵢₙ=V_{low}, no current runs through the first spin transistor 2, and a current runs through the second spin transistor 3, so that V_{high} input to the V_{high} node 32 of the second spin transistor 3 is output from Vₒᵤₜ.

(When Vᵢₙ=V_{high})

First, V_{high} is input as Vᵢₙ to the gate electrode 26 of the first spin transistor 2 and to the gate electrode 36 of the second spin transistor 3.

A spin-polarized electron 5 is injected into the 2 DEG channel 24 from the V_{low} node 22 of the first spin transistor 2.

This electron 5 precesses, for example, at an angle 2π around the z axis due to an effective magnetic field in the 2 DEG channel 24, and reaches the border between the 2 DEG channel 24 and the output node 6.

The electron 5 which has reached the border has a spin direction that differs by an angle 2π from the direction of majority spins of the output node 6, and therefore penetrates the border.

On the other hand, a spin-polarized electron 5 is injected into the 2 DEG channel 34 from the output node 6 of the second spin transistor 3.

This electron 5 precesses, for example, at an angle 3π around the z axis due to an effective magnetic field in the 2 DEG channel 34, and reaches the border between the 2 DEG channel 34 and the V_{high} node 32.

The electron 5 which has reached the border has a spin direction that differs by an angle 3π from the direction of majority spins of the V_{high} node 32, and is therefore reflected at the border.

Accordingly, in the integrated circuit 1, when Vᵢₙ=V_{high}, a current runs through the first spin transistor 2, and no current runs through the second spin transistor 3, so that V_{low} input to the V_{low} node 22 of the first spin transistor 2 is output from Vₒᵤₜ.

Thus, the integrated circuit 1 comprises an inverter circuit which outputs V_{high} as Vₒᵤₜ when V_{low} is input as Vᵢₙ and which outputs V_{low} as Vₒᵤₜ when V_{high} is input as Vᵢₙ.

### Advantages of the Sixth Embodiment

In the integrated circuit 1 according to the sixth embodiment, the substrate potentials Vₛₙ and Vₛₚ are equal, so that no element isolation region is needed. Therefore, as compared with an integrated circuit which requires an element isolation region, the area for placing the integrated circuit can be smaller.

### Seventh Embodiment

The seventh embodiment is different from the other embodiments described above in that Vₛₙ=Vₛₚ=GND.

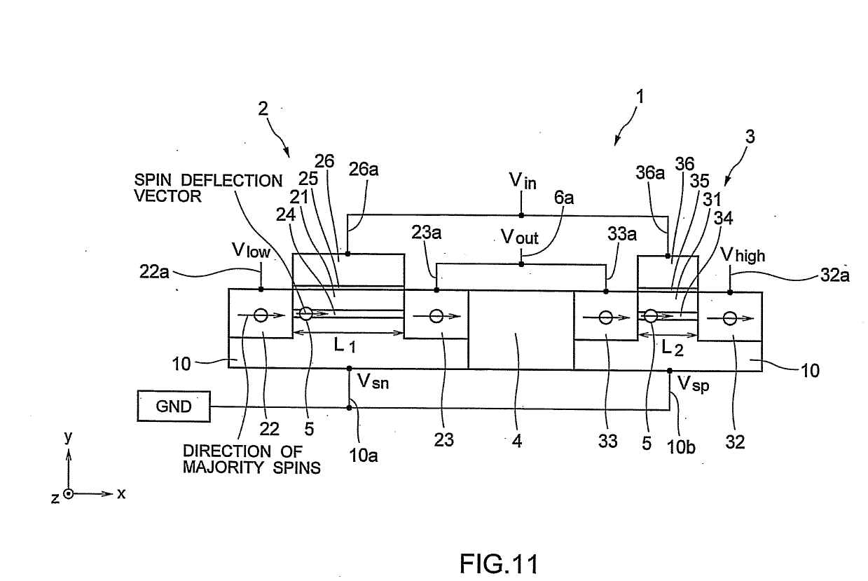

FIG. 11 is a schematic diagram of an integrated circuit according to the seventh embodiment. As shown in FIG. 11, in the integrated circuit 1 according to the present embodiment, the terminal 10a and the terminal 10b of the integrated circuit according to the first embodiment are connected to GND. Thus, in accordance with Expressions (5) to (8), V_{low}=Vₙ^{off}, V_{low}=Vₚ^{on}, V_{high}=Vₙ^{on}, and V_{high}=Vₚ^{off} are satisfied. Therefore, voltages Vₙ^{on}, Vₙ^{off}, Vₚ^{on}, and Vₚ^{off} can be simultaneously set by setting, for example, digital signals V_{low} and V_{high}.

The integrated circuit 1 according to the present embodiment is similar to the integrated circuit 1 according to the first embodiment except that the substrate potentials are Vₛₙ=Vₛₚ=GND, so that the operation of the integrated circuit 1 according to the present embodiment is also same as that in the first embodiment. Thus, the integrated circuit 1 according to the present embodiment comprises an inverter circuit which outputs V_{high} as Vₒᵤₜ when V_{low} is input as Vᵢₙ and which outputs V_{low} as Vₒᵤₜ when V_{high} is input as Vᵢₙ.

### Advantages of the Seventh Embodiment

In the integrated circuit 1 according to the seventh embodiment, the digital signals V_{low} and V_{high}, and the voltages Vₙ^{on}, Vₙ^{off}, Vₚ^{on}, and Vₚ^{off} can be easily set by setting the substrate potentials to Vₛₙ=Vₛₚ=GND.

### Eighth Embodiment

The eighth embodiment is different from the embodiments described above in that the substrate potentials of the integrated circuit according to the fifth embodiment are connected to GND.

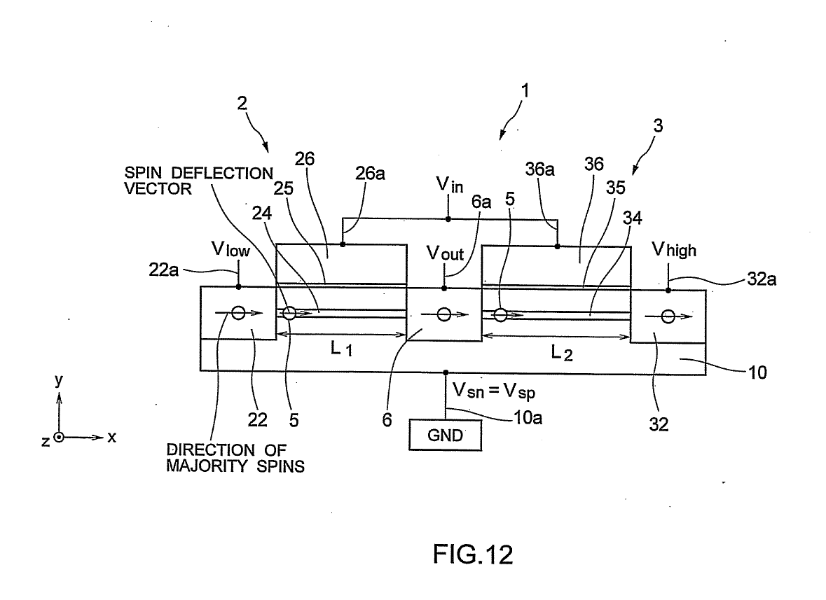

FIG. 12 is a schematic diagram of an integrated circuit according to the eighth embodiment. As shown in FIG. 12, in the integrated circuit 1 according to the eighth embodiment, the terminal 10a of the integrated circuit according to the fifth embodiment is connected to GND. Thus, as in the seventh embodiment, in accordance with Expressions (5) to (8), V_{low}=Vₙ^{off}, V_{low}=Vₚ^{on}, V_{high}=Vₙ^{on}, and V_{high}=Vₚ^{off} are satisfied. Therefore, voltages Vₙ^{on}, Vₙ^{off}, Vₚ^{on}, and Vₚ^{off} can be simultaneously set by setting, for example, digital signals V_{low} and V_{high}.

The integrated circuit 1 according to the present embodiment is similar to the integrated circuit 1 according to the fifth embodiment except that the substrate potentials are Vₛₙ=Vₛₚ=GND, so that the operation of the integrated circuit 1 according to the present embodiment is also same as that in the fifth embodiment. Thus, the integrated circuit 1 according to the present embodiment comprises an inverter circuit which outputs V_{high} as Vₒᵤₜ when V_{low} is input as Vᵢₙ and which outputs V_{low} as Vₒᵤₜ when V_{high} is input as Vᵢₙ.

### Advantages of the Eighth Embodiment

In the integrated circuit 1 according to the eighth embodiment, the substrate potentials are Vₛₙ=Vₛₚ=GND, so that no element isolation region is needed. Therefore, as compared with an integrated circuit which requires an element isolation region, the area for placing the integrated circuit can be smaller. Moreover, the digital signals V_{low} and V_{high}, and the voltages Vₙ^{on}, Vₙ^{off}, Vₚ^{on}, and Vₚ^{off} can be easily set.

### Ninth Embodiment

The ninth embodiment is different from the other embodiments described above in that a NAND circuit is configured by using a complementary circuit comprising spin transistors.

(Configuration of NAND Circuit 100a)

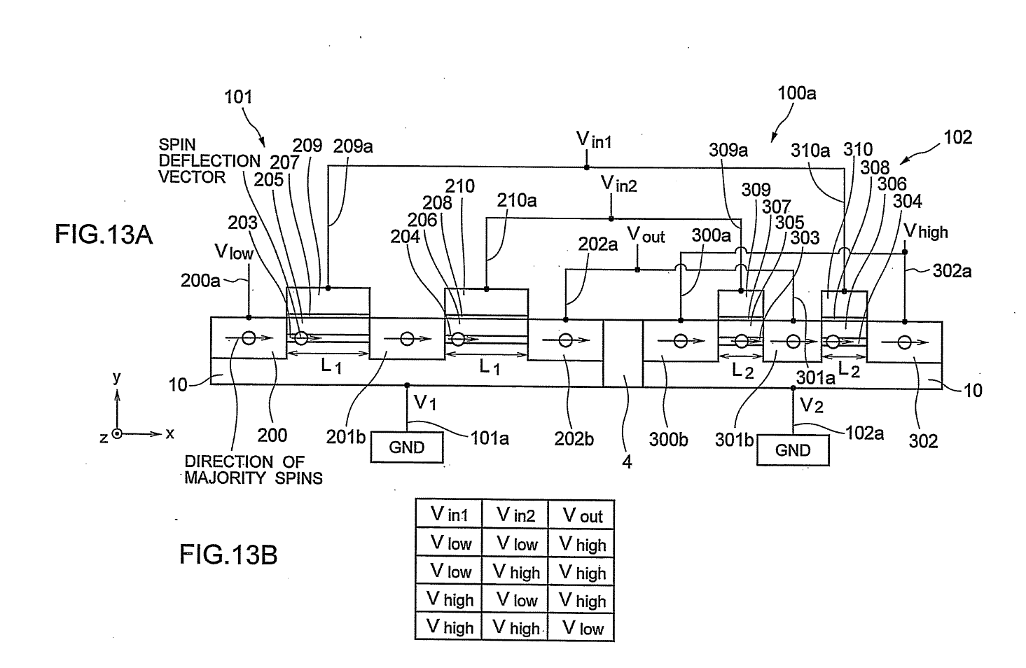

FIG. 13A is a schematic diagram of a NAND circuit according to the ninth embodiment. FIG. 13B is a logical operation table of the NAND circuit. In a NAND circuit 100a according to the present embodiment, a first element 101 and a second element 102 comprising spin transistors that are located across an element isolation region 4 are connected to each other in series between a power supply voltage V_{low} and a power supply voltage V_{high}.

As shown in FIG. 13A, in the first element 101, a V_{low} node 200, an intermediate node 201b, and an output node 202b are formed side by side on a semiconductor substrate 10 so that the channel length of each node is L₁. A 2 DEG channel 203 having the channel length L₁ is formed between the V_{low} node 200 and the intermediate node 201b, and a 2 DEG channel 204 having the channel length L₁ is formed between the intermediate node 201b and the output node 202b.

A semiconductor layer 205 is formed above the 2 DEG channel 203, and a gate electrode 209 is formed above the semiconductor layer 205 across a gate insulating film 207.

A semiconductor layer 206 is formed above the 2 DEG channel 204, and a gate electrode 210 is formed above the semiconductor layer 206 across a gate insulating film 208.

The V_{low} node 200 has a terminal 200a, and the power supply voltage V_{low} is supplied to the terminal 200a from a power supply circuit. The output node 202b has a terminal 202a.

The gate electrode 209 has a terminal 209a. The gate electrode 210 has a terminal 210a.

A substrate potential V₁ of the first element 101 is grounded.

As shown in FIG. 13A, in the second element 102, a V_{high} node 300b, an output node 301b, and a V_{high} node 302 are formed side by side on the semiconductor substrate 10 so that the channel length of each node is L₂. A 2 DEG channel 303 having the channel length L₂ is formed between the V_{high} node 300b and the intermediate node 301b, and a 2 DEG channel 304 having the channel length L₂ is formed between the output node 301b and the V_{high} node 302.

A semiconductor layer 305 is formed above the 2 DEG channel 303, and a gate electrode 309 is formed above the semiconductor layer 305 across a gate insulating film 307.

A semiconductor layer 306 is formed above the 2 DEG channel 304, and a gate electrode 310 is formed above the semiconductor layer 306 across a gate insulating film 308.

The V_{high} node 300b has a terminal 300a. The output node 301b has a terminal 301a, is connected to the terminal 202a of the output node 202b of the first element 101, and outputs Vₒᵤₜ. The V_{high} node 302 has a terminal 302a, and the power supply voltage V_{high} is supplied to the terminal 302a from the power supply circuit. This terminal 302a is connected to the terminal 300a of the V_{high} node 300b and to a terminal 102a of the semiconductor substrate 10 of the second element 102.

The gate electrode 309 has a terminal 309a. This terminal 309a is connected to the terminal 210a of the gate electrode 210 of the first element 101, and a digital signal Vᵢₙ₂ is input to the terminal 309a. The gate electrode 310 has a terminal 310a. This terminal 310a is connected to the terminal 209a of the gate electrode 209 of the first element 101, and a digital signal Vᵢₙ₁ is input to the terminal 310a.

A substrate potential V₂ of the second element 102 is grounded.

The operation of the NAND circuit 100a is described below with reference to the logical operation table shown in FIG. 13B.

(Operation)

Hereinafter, the channel length L₁ of the first element 101 is L, and the channel length L₂ of the second element 102 is L/2. That is, when the voltage V_{low} is applied to the gate electrode, an electron 5 traveling through the 2 DEG channel having the channel length L₁ precesses, for example, at an angle π. When the voltage V_{high} is applied to the gate electrode, an electron 5 traveling through the 2 DEG channel having the channel length L₁ precesses, for example, at an angle 2π. When the voltage V_{low} is applied to the gate electrode, an electron 5 traveling through the 2 DEG channel having the channel length L₂ precesses, for example, at an angle π/2. When the voltage V_{high} is applied to the gate electrode, an electron 5 traveling through the 2 DEG channel having the channel length L₂ precesses, for example, at an angle π.

(When Vᵢₙ₁=V_{low} and Vᵢₙ₂=V_{low})

First, V_{low} is input as Vᵢₙ₁ to the gate electrode 209 of the first element 101 and to the gate electrode 310 of the second element 102. V_{low} is also input as Vᵢₙ₂ to the gate electrode 210 of the first element 101 and to the gate electrode 309 of the second element 102.

A spin-polarized electron 5 is injected into the 2 DEG channel 203 from the V_{low} node 200 of the first element 101.

This electron 5 precesses, for example, at an angle π around the z axis due to an effective magnetic field in the 2 DEG channel 203, and reaches the border between the 2 DEG channel 203 and the intermediate node 201b.

The electron 5 which has reached the border has a spin direction that differs by an angle π from the direction of majority electron spins of the intermediate node 201b, and is therefore reflected at the border. That is, the electron 5 cannot penetrate the intermediate node 201b, so that no current runs through the first element 101.

On the other hand, a spin-polarized electron 5 is injected into the 2 DEG channel 303 and the 2 DEG channel 304 from the output node 301b of the second element 102.

This electron 5 precesses, for example, at an angle π/2 around the z axis due to an effective magnetic field in the 2 DEG channel 303, and reaches the border between the 2 DEG channel 303 and the V_{high} node 300b. The angle π/2 of the precession is attributed to the fact that the channel length L₂ of the second element 102 is half the channel length L₁ of the first element 101.

The electron 5 which has reached the border has a spin direction that differs by an angle π/2 from the direction of majority spins of the V_{high} node 300b, and therefore penetrates the border.

An electron 5 also precesses, for example, at an angle π/2 around the z axis due to an effective magnetic field in the 2 DEG channel 304, and reaches the border between the 2 DEG channel 304 and the V_{high} node 302.

The electron 5 which has reached the border has a spin direction that differs by an angle π/2 from the direction of majority spins of the V_{high} node 302, and therefore penetrates the border. That is, the potential of the output node 301b is V_{high}.

Accordingly, in the integrated circuit 1, when Vᵢₙ₁=V_{low} and Vᵢₙ₂=V_{low}, no current runs through the first element 101, and a current runs through the second element 102, so that V_{high} is output from Vₒᵤₜ.

(When Vᵢₙ₁=V_{low} and Vᵢₙ₂=V_{high})

First, V_{low} is input as Vᵢₙ₁ to the gate electrode 209 of the first element 101 and to the gate electrode 310 of the second element 102. V_{high} is also input as Vᵢₙ₂ to the gate electrode 210 of the first element 101 and to the gate electrode 309 of the second element 102.

A spin-polarized electron 5 is injected into the 2 DEG channel 203 from the V_{low} node 200 of the first element 101.

This electron 5 precesses, for example, at an angle π around the z axis due to an effective magnetic field in the 2 DEG channel 203, and reaches the border between the 2 DEG channel 203 and the intermediate node 201b.

The electron 5 which has reached the border has a spin direction that differs by an angle π from the direction of majority electron spins of the intermediate node 201b, and is therefore reflected at the border. That is, the electron 5 cannot penetrate the intermediate node 201b, so that no current runs through the first element 101.

On the other hand, a spin-polarized electron 5 is injected into the 2 DEG channel 303 and the 2 DEG channel 304 from the output node 301b of the second element 102.

This electron 5 precesses, for example, at an angle π around the z axis due to an effective magnetic field in the 2 DEG channel 303, and reaches the border between the 2 DEG channel 303 and the V_{high} node 300b.

The electron 5 which has reached the border has a spin direction that differs by an angle π from the direction of majority spins of the V_{high} node 300b, and is therefore reflected at the border.

An electron 5 also precesses, for example, at an angle π/2 around the z axis due to an effective magnetic field in the 2 DEG channel 304, and reaches the border between the 2 DEG channel 304 and the V_{high} node 302.

The electron 5 which has reached the border has a spin direction that differs by an angle π/2 from the direction of majority spins of the V_{high} node 302, and therefore penetrates the border. That is, the potential of the output node 301b is V_{high}.

Accordingly, in the integrated circuit 1, when Vᵢₙ₁=V_{low} and Vᵢₙ₂=V_{high}, no current runs through the first element 101, and a current runs through the second element 102, so that V_{high} is output from Vₒᵤₜ.

(When Vᵢₙ₁=V_{high} and Vᵢₙ₂=V_{low})

First, V_{high} is input as Vᵢₙ₁ to the gate electrode 209 of the first element 101 and to the gate electrode 310 of the second element 102. V_{low} is also input as Vᵢₙ₂ to the gate electrode 210 of the first element 101 and to the gate electrode 309 of the second element 102.

A spin-polarized electron 5 is injected into the 2 DEG channel 203 from the V_{low} node 200 of the first element 101.

This electron 5 precesses, for example, at an angle 2π around the z axis due to an effective magnetic field in the 2 DEG channel 203, and reaches the border between the 2 DEG channel 203 and the intermediate node 201b.

The electron 5 which has reached the border has a spin direction that differs by an angle 2π from the direction of majority electron spins of the intermediate node 201b, and therefore penetrates the border.

Furthermore, a spin-polarized electron 5 is injected into the 2 DEG channel 204 from the intermediate node 201b of the first element 101.

This electron 5 precesses, for example, at an angle π around the z axis due to an effective magnetic field in the 2 DEG channel 204, and reaches the border between the 2 DEG channel 204 and the output node 202b.

The electron 5 which has reached the border has a spin direction that differs by an angle π from the direction of majority electron spins of the output node 202b, and is therefore reflected at the border. That is, no current runs through the first element 101.

On the other hand, a spin-polarized electron 5 is injected into the 2 DEG channel 303 and the 2 DEG channel 304 from the output node 301b of the second element 102.

This electron 5 precesses, for example, at an angle π/2 around the z axis due to an effective magnetic field in the 2 DEG channel 303, and reaches the border between the 2 DEG channel 303 and the V_{high} node 300b.

The electron 5 which has reached the border has a spin direction that differs by an angle π/2 from the direction of majority spins of the V_{high} node 300b, and therefore penetrates the border.

An electron 5 also precesses, for example, at an angle π around the z axis due to an effective magnetic field in the 2 DEG channel 304, and reaches the border between the 2 DEG channel 304 and the V_{high} node 302.

The electron 5 which has reached the border has a spin direction that differs by an angle π from the direction of majority spins of the V_{high} node 302, and is therefore reflected at the border. However, a current runs across the output node 301b and the V_{high} node 300b, so that the potential of the output node 301b is V_{high}.

Accordingly, in the integrated circuit 1, when Vᵢₙ₁=V_{high} and Vᵢₙ₂=V_{low}, no current runs through the first element 101, and a current runs across the output node 301b and the V_{high} node 302 of the second element 102, so that V_{high} is output from Vₒᵤₜ.

(When Vᵢₙ₁=V_{high} and Vᵢₙ₂=V_{high})

First, V_{high} is input as Vᵢₙ₁ to the gate electrode 209 of the first element 101 and to the gate electrode 310 of the second element 102. V_{high} is also input as Vᵢₙ₂ to the gate electrode 210 of the first element 101 and to the gate electrode 309 of the second element 102.

A spin-polarized electron 5 is injected into the 2 DEG channel 203 from the V_{low} node 200 of the first element 101.

This electron 5 precesses, for example, at an angle 2π around the z axis due to an effective magnetic field in the 2 DEG channel 203, and reaches the border between the 2 DEG channel 203 and the intermediate node 201b.

The electron 5 which has reached the border has a spin direction that differs by an angle 2π from the direction of majority electron spins of the intermediate node 201b, and therefore penetrates the border.

Furthermore, a spin-polarized electron 5 is injected into the 2 DEG channel 204 from the intermediate node 201b of the first element 101.

This electron 5 precesses, for example, at an angle 2π around the z axis due to an effective magnetic field in the 2 DEG channel 204, and reaches the border between the 2 DEG channel 204 and the output node 202b.

The electron 5 which has reached the border has a spin direction that differs by an angle 2π from the direction of majority electron spins of the output node 202b, and therefore penetrates the border. That is, the potential of the output node 202b is V_{low}.

On the other hand, a spin-polarized electron 5 is injected into the 2 DEG channel 303 and the 2 DEG channel 304 from the output node 301b of the second element 102.

This electron 5 precesses, for example, at an angle π around the z axis due to an effective magnetic field in the 2 DEG channel 303, and reaches the border between the 2 DEG channel 303 and the V_{high} node 300b.

The electron 5 which has reached the border has a spin direction that differs by an angle π from the direction of majority spins of the V_{high} node 300b, and is therefore reflected at the border.

An electron 5 also precesses, for example, at an angle π around the z axis due to an effective magnetic field in the 2 DEG channel 304, and reaches the border between the 2 DEG channel 304 and the V_{high} node 302.

The electron 5 which has reached the border has a spin direction that differs by an angle π from the direction of majority spins of the V_{high} node 302, and is therefore reflected at the border. That is, no current runs through the second element 102.

Accordingly, in the integrated circuit 1, when Vᵢₙ₁V_{high} and Vᵢₙ₂=V_{high}, a current runs through the first element 101, and no current runs through the second element 102, so that V_{low} is output from Vₒᵤₜ.

Consequently, the NAND circuit 100a satisfies the logical operation table shown in FIG. 13B, and therefore comprises a NAND circuit.

### Advantages of the Ninth Embodiment

The NAND circuit 100a according to the ninth embodiment comprises the spin transistors different in channel length that are connected in series. Therefore, as compared with a NAND circuit which comprises a CMOS transistor, there is no need for separate p-type and n-type transistors, leading to fewer manufacturing processes and reduced manufacturing costs.

### Tenth Embodiment

The tenth embodiment is different from the other embodiments described above in that a NOR circuit is configured by using a complementary circuit comprising spin transistors.

(Configuration of NOR Circuit 100b)

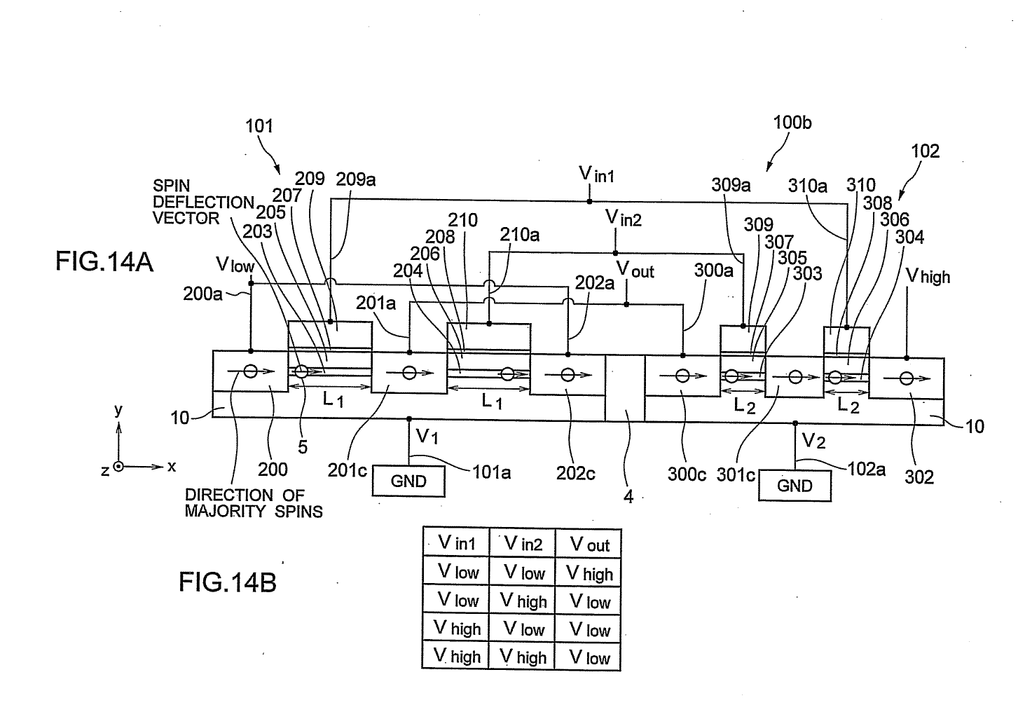

FIG. 14A is a schematic diagram of a NOR circuit according to the tenth embodiment. FIG. 14B is a logical operation table of the NOR circuit. The basic configuration of a NOR circuit 100b according to the present embodiment is the same as that of the NAND circuit 100a according to the ninth embodiment. However, the NOR circuit 100b is different from the NAND circuit 100a in the connection of terminals. In the present embodiment, the differences between the ninth embodiment and the tenth embodiment are mainly described.

As shown in FIG. 14A, in a first element 101, a power supply voltage V_{low} is supplied to a V_{low} node 200 from a power supply circuit. A terminal 200a of the V_{low} node 200 is connected to a terminal 202a of a V_{low} node 202c. A terminal 201a of an output node 201c is connected to a terminal 300a of an output node 300c of a second element 102. A substrate potential V₁ is grounded.

In the second element 102, a power supply voltage V_{high} is supplied to a V_{high} node 302 from the power supply circuit. A substrate potential V₂ is grounded.

The operation of the NOR circuit 100b is described below with reference to the logical operation table shown in FIG. 14B.

(Operation)

Hereinafter, a channel length L₁ of the first element 101 is L, and a channel length L₂ of the second element 102 is L/2.

(When Vᵢₙ₁=V_{low} and Vᵢₙ₂=V_{low})

First, V_{low} is input as Vᵢₙ₁ to a gate electrode 209 of the first element 101 and to a gate electrode 310 of the second element 102. V_{low} is also input as Vᵢₙ₂ to a gate electrode 210 of the first element 101 and to a gate electrode 309 of the second element 102.

A spin-polarized electron 5 is injected into a 2 DEG channel 203 from the V_{low} node 200 of the first element 101.

This electron 5 precesses, for example, at an angle π around the z axis due to an effective magnetic field in the 2 DEG channel 203, and reaches the border between the 2 DEG channel 203 and the output node 201c.

The electron 5 which has reached the border has a spin direction that differs by an angle π from the direction of majority electron spins of the output node 201c, and is therefore reflected at the border.

A spin-polarized electron 5 is also injected into a 2 DEG channel 204 from the V_{low} node 202c of the first element 101.

This electron 5 precesses, for example, at an angle π around the z axis due to an effective magnetic field in the 2 DEG channel 204, and reaches the border between the 2 DEG channel 204 and the output node 202c.

The electron 5 which has reached the border has a spin direction that differs by an angle π from the direction of majority electron spins of the output node 201c, and is therefore reflected at the border. That is, no current runs through the first element 101.

On the other hand, a spin-polarized electron 5 is injected into a 2 DEG channel 303 from the output node 300c of the second element 102.

This electron 5 precesses, for example, at an angle π/2 around the z axis due to an effective magnetic field in the 2 DEG channel 303, and reaches the border between the 2 DEG channel 303 and an intermediate node 301c.

The electron 5 which has reached the border has a spin direction that differs by an angle π/2 from the direction of majority spins of the intermediate node 301c, and therefore penetrates the border.

Furthermore, a spin-polarized electron 5 is injected into a 2 DEG channel 304 from the intermediate node 301c of the second element 102.

This electron 5 precesses, for example, at an angle π/2 around the z axis due to an effective magnetic field in the 2 DEG channel 304, and reaches the border between the 2 DEG channel 304 and the V_{high} node 302.

The electron 5 which has reached the border has a spin direction that differs by an angle π/2 from the direction of majority spins of the V_{high} node 302, and therefore penetrates the border. That is, the potential of the output node 300c is V_{high}.

Accordingly, in the integrated circuit 1, when Vᵢₙ₁=V_{low} and Vᵢₙ₂=V_{low}, no current runs through the first element 101, and a current runs through the second element 102, so that V_{high} is output from Vₒᵤₜ.

(When Vᵢₙ₁=V_{low} and Vᵢₙ₂=V_{high})

First, V_{low} is input as Vᵢₙ₁ to the gate electrode 209 of the first element 101 and to the gate electrode 310 of the second element 102. V_{high} is also input as Vᵢₙ₂ to the gate electrode 210 of the first element 101 and to the gate electrode 309 of the second element 102.

A spin-polarized electron 5 is injected into the 2 DEG channel 203 from the V_{low} node 200 of the first element 101.

This electron 5 precesses, for example, at an angle π around the z axis due to an effective magnetic field in the 2 DEG channel 203, and reaches the border between the 2 DEG channel 203 and the output node 201c.

The electron 5 which has reached the border has a spin direction that differs by an angle π from the direction of majority electron spins of the output node 201c, and is therefore reflected at the border.

A spin-polarized electron 5 is also injected into the 2 DEG channel 204 from the V_{low} node 202c of the first element 101.

This electron 5 precesses, for example, at an angle 2π around the z axis due to an effective magnetic field in the 2 DEG channel 204, and reaches the border between the 2 DEG channel 204 and the output node 201c.

The electron 5 which has reached the border has a spin direction that differs by an angle 2π from the direction of majority electron spins of the output node 201c, and therefore penetrates the border. That is, the potential of the output node 201c

is V_{low}.

On the other hand, a spin-polarized electron 5 is injected into the 2 DEG channel 303 from the output node 300c of the second element 102.

This electron 5 precesses, for example, at an angle π around the z axis due to an effective magnetic field in the 2 DEG channel 303, and reaches the border between the 2 DEG channel 303 and the intermediate node 301c.

The electron 5 which has reached the border has a spin direction that differs by an angle π from the direction of majority spins of the intermediate node 301c, and is therefore reflected at the border. Thus, no current runs through the second element 102.

Accordingly, in the integrated circuit 1, when Vᵢₙ₁=V_{low} and Vᵢₙ₂=V_{high}, a current runs through the first element 101, and no current runs through the second element 102, so that V_{low} is output from Vₒᵤₜ.

(When Vᵢₙ₁=V_{high} and Vᵢₙ₂=V_{low})

First, V_{high} is input as Vᵢₙ₁ to the gate electrode 209 of the first element 101 and to the gate electrode 310 of the second element 102. V_{low} is also input as Vᵢₙ₂ to the gate electrode 210 of the first element 101 and to the gate electrode 309 of the second element 102.

A spin-polarized electron 5 is injected into the 2 DEG channel 203 from the V_{low} node 200 of the first element 101.

This electron 5 precesses, for example, at an angle 2π around the z axis due to an effective magnetic field in the 2 DEG channel 203, and reaches the border between the 2 DEG channel 203 and the output node 201c.

The electron 5 which has reached the border has a spin direction that differs by an angle 2π from the direction of majority spins of the output node 201c, and therefore penetrates the border.

A spin-polarized electron 5 is also injected into the 2 DEG channel 204 from the V_{low} node 202c of the first element 101.

This electron 5 precesses, for example, at an angle π around the z axis due to an effective magnetic field in the 2 DEG channel 204, and reaches the border between the 2 DEG channel 204 and the V_{low} node 202c.

The electron 5 which has reached the border has a spin direction that differs by an angle π from the direction of majority electron spins of the output node 201c, and is therefore reflected at the border. However, a current runs across the V_{low} node 200 and the output node 201c, so that the potential of the output node 201c is V_{low}.

On the other hand, a spin-polarized electron 5 is injected into the 2 DEG channel 303 from the output node 300c of the second element 102.

This electron 5 precesses, for example, at an angle π/2 around the z axis due to an effective magnetic field in the 2 DEG channel 303, and reaches the border between the 2 DEG channel 303 and the intermediate node 301c.

The electron 5 which has reached the border has a spin direction that differs by an angle π/2 from the direction of majority spins of the intermediate node 301c, and therefore penetrates the border.

Furthermore, a spin-polarized electron 5 is injected into the 2 DEG channel 304 from the intermediate node 301c of the second element 102.

This electron 5 precesses, for example, at an angle π around the z axis due to an effective magnetic field in the 2 DEG channel 304, and reaches the border between the 2 DEG channel 304 and the V_{high} node 302.

The electron 5 which has reached the border has a spin direction that differs by an angle π from the direction of majority spins of the V_{high} node 302, and is therefore reflected at the border. Thus, no current runs through the second element 102.

Accordingly, in the integrated circuit 1, when Vᵢₙ₁=V_{high} and Vᵢₙ₂=V_{low}, a current runs through the first element 101, and no current runs through the second element 102, so that V_{low} is output from Vₒᵤₜ.

(When Vᵢₙ₁=V_{high} and Vᵢₙ₂=V_{high})

First, V_{high} is input as Vᵢₙ₁ to the gate electrode 209 of the first element 101 and to the gate electrode 310 of the second element 102. V_{high} is also input as Vᵢₙ₂ to the gate electrode 210 of the first element 101 and to the gate electrode 309 of the second element 102.

A spin-polarized electron 5 is injected into the 2 DEG channel 203 from the V_{low} node 200 of the first element 101.

This electron 5 precesses, for example, at an angle 2π around the z axis due to an effective magnetic field in the 2 DEG channel 203, and reaches the border between the 2 DEG channel 203 and the output node 201c.

The electron 5 which has reached the border has a spin direction that differs by an angle 2π from the direction of majority electron spins of the output node 201c, and therefore penetrates the border.

A spin-polarized electron 5 is also injected into the 2 DEG channel 204 from the V_{low} node 202c of the first element 101.

This electron 5 precesses, for example, at an angle 2π around the z axis due to an effective magnetic field in the 2 DEG channel 204, and reaches the border between the 2 DEG channel 204 and the output node 201c.

The electron 5 which has reached the border has a spin direction that differs by an angle 2π from the direction of majority electron spins of the output node 201c, and therefore penetrates the border. That is, the potential of the output node 201c is V_{low}.

On the other hand, a spin-polarized electron 5 is injected into the 2 DEG channel 303 from the output node 300c of the second element 102.

This electron 5 precesses, for example, at an angle π around the z axis due to an effective magnetic field in the 2 DEG channel 303, and reaches the border between the 2 DEG channel 303 and the intermediate node 301c.

The electron 5 which has reached the border has a spin direction that differs by an angle π from the direction of majority spins of the intermediate node 301c, and is therefore reflected at the border. Thus, no current runs through the second element 102.

Accordingly, in the integrated circuit 1, when Vᵢₙ₁=V_{high} and Vᵢₙ₂=V_{high}, a current runs through the first element 101, and no current runs through the second element 102, so that V_{low} is output from Vₒᵤₜ.

Consequently, the NOR circuit 100b satisfies the logical operation table shown in FIG. 14B, and therefore comprises a NOR circuit.

### Advantages of the Tenth Embodiment

The NOR circuit 100b according to the tenth embodiment comprises the spin transistors different in channel length that are connected in series. Therefore, as compared with a NOR circuit which comprises a CMOS transistor, there is no need for separate p-type and n-type transistors, leading to fewer manufacturing processes and reduced manufacturing costs.

According to the embodiments described above, a logical operation circuit can be formed by using spin transistors different in channel length.

Moreover, according to the embodiments described above, the source region and the drain region are formed by a ferromagnetic body. This makes it possible to prevent, for example, a short channel effect such as a gate leakage and drain induced-barrier lowering (DIBL), and gate induced drain leakage (GIDL) caused by inhibiting the short channel effect. In the integrated circuit 1 according to each of the embodiments, the width of V_{high} and V_{low} for switching on/off the first and second spin transistors 2 and 3 can be small, so that power consumption is low.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. An integrated circuit comprising:
a first spin transistor having a first channel length, the first spin transistor comprising a first node and a second node apart from the first node; and
a second spin transistor which is connected to the first spin transistor in series and which has a second channel length different from the first channel length, the second spin transistor comprising a third node and a fourth node apart from the third node,
wherein the second node and the fourth node are electrically connected to each other.

2. The circuit of claim 1,
wherein the first spin transistor comprises a first channel region between the first node and the second node, and a first gate electrode above the first channel region,
the second spin transistor comprises a second channel region between the third node and the fourth node, and a second gate electrode above the second channel region,
the first node is supplied with a first voltage, and
the third node is supplied with a second voltage.

3. The circuit of claim 2,
wherein a substrate potential of the first spin transistor, a substrate potential of the second spin transistor, and a potential of the first node are the same.

4. The circuit of claim 2,
wherein a material of the first gate electrode is the same as a material of the second gate electrode.

5. The circuit of claim 2,
wherein the first and second gate electrodes are electrically connected to each other, and a substrate potential of the first spin transistor, a substrate potential of the second spin transistor, and a potential of the third node are the same.

6. The circuit of claim 2,
wherein a substrate potential of the first spin transistor and a potential of the third node are the same, and a substrate potential of the second spin transistor and a potential of the first node are the same.

7. The circuit of claim 2,
wherein the first and second gate electrodes are electrically connected to each other, and
both a substrate of the first spin transistor and a substrate of the second spin transistor are grounded.

8. The circuit of claim 1,
wherein the first spin transistor comprises a fifth node between the first node and the second node, a first channel region between the first node and the fifth node, a first gate electrode above the first channel region, a second channel region between the fifth node and the second node, and a second gate electrode above the second channel region,
the second spin transistor comprises a sixth node apart from the fourth node on the side opposite the third node, a third channel region between the third node and the fourth node, a third gate electrode above the third channel region, a fourth channel region between the fourth node and the sixth node, and a fourth gate electrode above the fourth channel region,
the first node is supplied with a first voltage,
the third node is supplied with a second voltage,
the first and third gate electrodes are electrically connected to each other,
the second and fourth gate electrodes are electrically connected to each other,
the third and sixth nodes are electrically connected to each other, and
a substrate potential of the first spin transistor and a substrate potential of the second spin transistor are the same.

9. The circuit of claim 8,
wherein the second channel length is half the first channel length.

10. The circuit of claim 1,
wherein the first spin transistor comprises a fifth node apart from the second node on the side opposite the first node, a first channel region between the first node and the second node, a first gate electrode above the first channel region, a second channel region between the second node and the fifth node, and a second gate electrode above the second channel region,
the second spin transistor comprises a sixth node between the third node and the fourth node, a third channel region between the third node and the sixth node, a third gate electrode above the third channel region, a fourth channel region between the fourth node and the sixth node, and a fourth gate electrode above the fourth channel region,
the first node is supplied with a first voltage,
the third node is supplied with a second voltage,
the first and third gate electrodes are electrically connected to each other,
the second and fourth gate electrodes are electrically connected to each other,
the first and fifth nodes are electrically connected to each other, and
a substrate potential of the first spin transistor and a substrate potential of the second spin transistor are the same.

11. The circuit of claim 10,
wherein the second channel length is half the first channel length.

12. The circuit of claim 1,
wherein nodes of the first and second spin transistors are formed by use of a high spin deflection material.

13. The circuit of claim 12,
wherein the high spin deflection material is a ferromagnetic metal.

14. The circuit of claim 13,
wherein the nodes of the first and second spin transistors
are made of a ferromagnetic body, the ferromagnetic body being consistent with a group III-V semiconductor, having a Curie temperature equal to or more than a room temperature, and having a wide band gap in the vicinity of a Fermi level E_{F} regarding the energy state of one spin.

15. The circuit of claim 14,
wherein the ferromagnetic body is a half metal ferromagnetic body having a band structure in which the Fermi level E_{F} traverses one spin band and traverses the band gap in the other spin band.

16. An integrated circuit comprising:
a first spin transistor, the first spin transistor comprising a first node supplied with a first voltage, a second node apart from the first node, a first channel region between the first node and the second node with a first channel length, and a first gate electrode; and
a second spin transistor configured to share the second node of the first spin transistor with the first spin transistor, the second spin transistor comprising a third node supplied with a second voltage, a second channel region between the second node and the third node with a second channel length different from the first channel length, and a second gate electrode.

17. The circuit of claim 16,
wherein the first and second gate electrodes are electrically connected to each other, and
a substrate potential of the first spin transistor, a substrate potential of the second spin transistor, and a potential of the first node are the same.

18. The circuit of claim 16,
wherein a material of the first node, a material of the second node, and a material of the third node are the same.

19. The circuit of claim 16,
wherein a substrate potential of the first spin transistor, a substrate potential of the second spin transistor, and a potential of the third node are the same.

20. The circuit of claim 16,
wherein the first and second gate electrodes are electrically connected to each other, and
both a substrate of the first spin transistor and a substrate of the second spin transistor are grounded.
